(19) United States
(12) Patent Application Publication
(10) Pub. No.: US 2021/0043993 A1
(43) Pub. Date: Feb. 11, 2021

(54) FILTER AND MULTIPLEXER

(71) Applicant: Murata Manufacturing Co., Ltd., Nagaokakyo-shi (JP)

(72) Inventor: Shinichi NAKAMURA, Nagaokakyo-shi (JP)

(21) Appl. No.: 17/083,360

(22) Filed: Oct. 29, 2020

Related U.S. Application Data
(63) Continuation of application No. PCT/JP2019/022301, filed on Jun. 5, 2019.

(30) Foreign Application Priority Data
Jun. 5, 2018 (JP) 2018-107875

(51) Int. Cl. H01P 1/20; H03H 9/64

(52) U.S. Cl. CPC H01P 1/20; H03H 9/6406; H03H 9/6483

(57) ABSTRACT

A filter circuit includes a signal path connecting first and second terminals having a pass band. An additional circuit is connected to a node between the first terminal and the filter circuit on the signal path and a node between the second terminal and the filter circuit on the signal path. The additional circuit includes a parallel circuit including first and second resonator groups connected in parallel and capacitor elements connected in series to the parallel circuit. The first and second resonator groups each include IDT electrodes in line in an acoustic-wave propagation direction. The additional circuit generates a signal having a phase opposite to a phase of a signal component in a frequency band that is not included in the pass band, among signals transmitted through filter circuit.

### CROSS REFERENCE TO RELATED APPLICATIONS

This application claims the benefit of priority to Japanese Patent Application No. 2018-107875 filed on Jun. 5, 2018 and is a Continuation Application of PCT Application No. PCT/JP2019/022301 filed on Jun. 5, 2019. The entire contents of each application are hereby incorporated herein by reference.

### BACKGROUND OF THE INVENTION

### 1. Field of the Invention

The present invention relates to a filter and a multiplexer, each of which includes an additional circuit.

### 2. Description of the Related Art

Acoustic wave filters and multiplexers using the acoustic wave filters are required to improve attenuation characteristics and isolation characteristics between the filters. A radio-frequency filter including a filter portion having a pass band and a stop band in the related art is known to have a configuration in which an additional circuit portion is provided so as to be connected in parallel to the filter portion (for example, Japanese Unexamined Patent Application Publication No. 2014-171210). The additional circuit portion has a frequency domain having bandpass characteristics in the stop band. In the additional circuit portion, a signal passing through the additional circuit portion in the frequency domain has a phase component in a direction opposite to that of the phase component of a signal passing through the filter portion in the frequency domain.

However, when the filters have wide bandwidths, it is difficult to adjust the phase of the additional circuit portion over a desired frequency domain in the configuration in the related art such that it is difficult to achieve sufficient attenuation characteristics and isolation characteristics.

### SUMMARY OF THE INVENTION

Preferred embodiments of the present invention improve the attenuation characteristics and/or the isolation characteristics in filters and multiplexers, which each include an additional circuit to generate a signal having a phase opposite to that of a signal in a specific frequency band.

A filter according to a preferred embodiment of the present invention includes a filter circuit and an additional circuit that are connected in parallel to each other. The filter circuit has a pass band. The additional circuit includes a first resonator group and a second resonator group each of which includes multiple interdigital transducer electrodes arranged in line in an acoustic-wave propagation direction and which are connected in parallel to each other. The additional circuit generates a signal having a phase opposite to a phase of a signal component in a specific frequency band that is not included in the pass band, among signals transmitted through the filter circuit.

The filter generates a signal having a phase opposite to that of a signal component in a specific frequency band with the two resonator groups connected in parallel to each other. With this configuration, since the signal of the opposite phase is capable of being generated with lower loss and in a wider frequency band, compared with a case in which the signal of the opposite phase is generated with one resonator group, it is possible to obtain filters each having excellent attenuation characteristics.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram illustrating an exemplary configuration of a filter according to a first preferred embodiment of the present invention.

FIG. 2 is a circuit diagram illustrating an exemplary configuration of a filter circuit according to the first preferred embodiment of the present invention.

FIGS. 3A and 3B are schematic views illustrating an exemplary structure of an IDT electrode according to the first preferred embodiment of the present invention.

FIG. 4 is a circuit diagram illustrating an exemplary configuration of a filter according to a comparative example.

FIG. 5 is a graph showing examples of attenuation characteristics of the filter according to the first preferred embodiment of the present invention.

FIG. 6 is a circuit diagram illustrating an exemplary configuration of a multiplexer according to a second preferred embodiment of the present invention.

FIG. 7 is a graph showing examples of isolation characteristics of the multiplexer according to the second preferred embodiment of the present invention.

FIG. 8 is a circuit diagram illustrating another exemplary configuration of a multiplexer according to the second preferred embodiment of the present invention.

FIG. 9 is a circuit diagram illustrating another exemplary configuration of a multiplexer according to the second preferred embodiment of the present invention.

### DETAILED DESCRIPTION OF THE PREFERRED EMBODIMENTS

Preferred embodiments of the present invention will herein be described in detail with reference to the drawings. All of the preferred embodiments described below indicate comprehensive or specific examples. Numerical values, shapes, materials, components, the arrangement of the components, the connection configuration of the components, and so on, which are indicated in the preferred embodiments described below, are only examples and are not intended to limit the present invention.

### First Preferred Embodiment

A filter according to a first preferred embodiment of the present invention will now be described, providing an example of a filter in which a filter circuit having a pass band is connected in parallel to an additional circuit that generates a signal (hereinafter referred to as a cancel signal) having a phase opposite to that of a signal component outside the pass band, which is transmitted through the filter circuit.

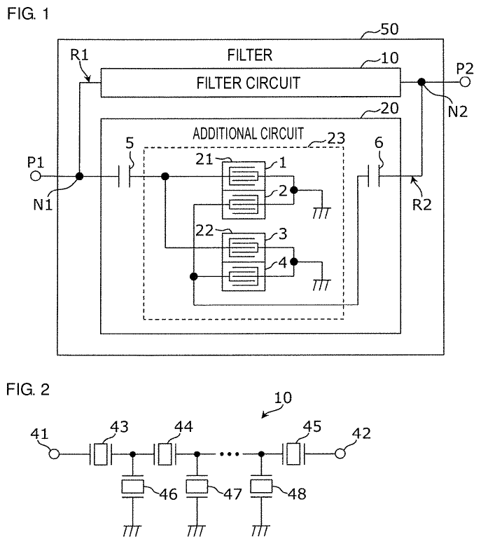

FIG. 1 is a circuit diagram illustrating an exemplary configuration of a filter according to the first preferred embodiment. As illustrated in FIG. 1, a filter 50 includes terminals P1 and P2, a filter circuit 10, and an additional circuit 20.

A radio-frequency signal is transmitted through the terminals P1 and P2. The direction in which the radio-frequency signal is transmitted between the terminals P1 and P2 is not limited.

The filter circuit 10 is a filter having a pass band and is, for example, a band pass filter, a low pass filter, or a high pass filter. One end of the filter circuit 10 is connected to the terminal P1 and the other end thereof is connected to the terminal P2 to define a signal path R1 with which the terminal P1 is connected to the terminal P2. One end and the other end of the filter circuit 10 may be directly connected to the terminals P1 and P2, respectively, or may be connected to the terminals P1 and P2, respectively, with other circuit elements (not illustrated) interposed therebetween.

The filter circuit 10 may be, for example, a ladder acoustic wave filter circuit including multiple acoustic wave resonators although the filter circuit 10 is not particularly limited.

FIG. 2 is a circuit diagram illustrating an exemplary configuration of the filter circuit 10. The filter circuit 10 in FIG. 2 is a ladder acoustic wave filter circuit including terminals 41 and 42, series-arm resonators 43, 44, and 45, and parallel-arm resonators 46, 47, and 48. The series-arm resonators 43, 44, and 45 and the parallel-arm resonators 46, 47, and 48 are each defined by a surface acoustic wave resonator.

The series-arm resonators 43, 44, and 45 are connected in series to each other to define a signal path with which the terminal 41 is connected to the terminal 42. The parallel-arm resonators 46, 47, and 48 are connected between the signal path including the series-arm resonators 43, 44, and 45 and ground. The numbers of the series-arm resonators and the parallel-arm resonators, which define the filter circuit 10, are not limited to the numbers in the example in FIG. 2. The filter circuit 10 may include, for example, one or more series-arm resonators and one or more parallel-arm resonators as the ladder acoustic wave filter circuit.

Referring back to FIG. 1, one end of the additional circuit 20 is connected to a node N1 between the terminal P1 and the filter circuit 10 on the signal path R1, and the other end of the additional circuit 20 is connected to a node N2 between the terminal P2 and the filter circuit 10 on the signal path R1. The additional circuit 20 defines a signal path R2 with which the node N1 is connected to the node N2.

The additional circuit 20 includes, on the signal path R2, a parallel circuit 23 in which resonator groups 21 and 22 are connected in parallel to each other and capacitor elements 5 and 6 connected in series to the parallel circuit 23.

The resonator group 21 includes IDT electrodes 1 and 2, and the resonator group 22 includes IDT electrodes 3 and 4. Each of the resonator groups 21 and 22 may include, for example, three or more IDT electrodes (not illustrated). The IDT electrodes of the resonator group 21 are disposed in line in a propagation direction of acoustic waves. Similarly, the IDT electrodes of the resonator group 22 are also disposed in line in the propagation direction of the acoustic waves.

Each of the resonator groups 21 and 22 may be, for example, a transversal filter in which a signal is transmitted using propagation of surface acoustic waves between the IDT electrodes or may be, for example, a longitudinally coupled resonator filter in which a signal is transmitted using coupling of the surface acoustic waves between the IDT electrodes.

The resonator groups 21 and 22 control the phase of the cancel signal, and the capacitor elements 5 and 6 control the amplitude of the cancel signal.

The additional circuit 20 generates the cancel signal against the signal component in a target frequency band that is not included in the pass band, among the signals transmitted through the filter circuit 10, with the above configuration. When the cancel signal is combined with the signal component to be cancelled, the amplitude of the result of the combination is smaller than the amplitude of the original signal component to be cancelled. The phase of the cancel signal is opposite to the phase of the signal component to be cancelled after being transmitted through the filter circuit 10 and the amplitude of the cancel signal is preferably the same or substantially the same as the amplitude of the signal component to be cancelled after being transmitted through the filter circuit 10.

Here, the fact that the phase of the signal component to be cancelled is opposite to the phase of the cancel signal means that the absolute value of the phase difference between the signal component to be cancelled and the cancel signal is greater than 90° within a range from −180° or more and 180° or less. This is equivalent to the fact that the phase component of the signal component to be cancelled is in a direction opposite to that of the phase component of the cancel signal.

Although the cancel signal preferably has the same or substantially the same amplitude as that of the signal component to be cancelled, the amplitude of the cancel signal may be different from that of the signal component to be cancelled. When the amplitude of the result of combination of the cancel signal and the signal component to be cancelled is smaller than the amplitude of the original signal component to be cancelled depending on the phase difference between the cancel signal and the signal component to be cancelled, it is possible to improve attenuation characteristics.

The frequency band in which the amplitude of the cancel signal is capable of being controlled with the capacitor elements 5 and 6 is fixed in accordance with the capacitance values of the capacitor elements 5 and 6. In other words, the additional circuit 20 generates the cancel signal against a signal component in a specific frequency band. The specific frequency band may be, for example, a frequency band determined based on the capacitance values of the capacitor elements 5 and 6.

The resonator groups 21 and 22 in the additional circuit 20 do not control the phases of the two cancel signals in two separate frequency bands separately but control the phases of the cancel signals in continuous frequency bands which are in a specific frequency band and at least a portion of which is overlapped. In other words, the additional circuit 20 controls the phases of the cancel signals in a specific frequency band with the two resonator groups 21 and 22 connected in parallel to each other.

When the phase of the cancel signal is controlled with one resonator group, the phase of the cancel signal may not be sufficiently controlled because of high insertion loss and phase characteristic of the narrow band of the resonator group.

In order to resolve this problem, the phases of the cancel signals in a specific frequency band are controlled with the two resonator groups 21 and 22 connected in parallel to each other. With this configuration, since the phases of the cancel signals are capable of being controlled with lower loss and in a wider frequency band, compared with the case in which the phase of the cancel signal is controlled with one resonator group, it is possible to obtain a filter having the excellent attenuation characteristics.

In order to further improve the attenuation characteristics of the filter, it is also effective to differentiate electrode parameters of the IDT electrodes 1 and 2 of the resonator group 21 from electrode parameters of the IDT electrodes 3 and 4 of the resonator group 22. The electrode parameters of the IDT electrodes mean parameters that define the shape, the size, and so on of the IDT electrodes.

When the electrode parameters of the IDT electrodes are differentiated, the frequency of an unnecessary response caused by the resonator group 21 is shifted from the frequency of an unnecessary response caused by the resonator group 22. This reduces the influence of the unnecessary responses on bandpass characteristics of the filter 50, compared with a case in which the parameters of the IDT electrodes of the resonator group 21 are equal or substantially equal to those of the IDT electrodes of the resonator group 22, that is, a case in which the frequency of the unnecessary response caused by the resonator group 21 coincides with that of the unnecessary response caused by the resonator group 22. As a result, it is possible to improve the insertion loss in the pass band, in addition to the improvement of the attenuation characteristics.

A typical structure of the IDT electrode will now be described for understanding of the electrode parameters.

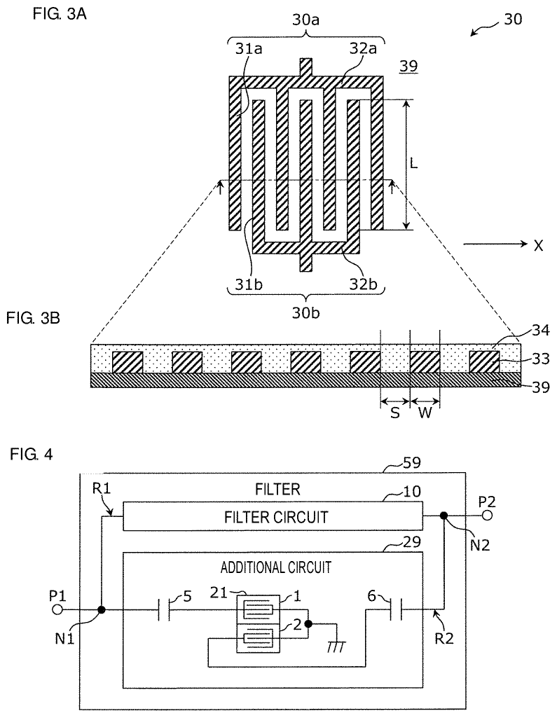

FIGS. 3A and 3B include schematic views illustrating an exemplary structure of an IDT electrode 30. FIG. 3A is a plan view and 3B is a side view. FIG. 3B corresponds to a cross section along an alternate long and short dash line illustrated in FIG. 3A. The structure illustrated in FIGS. 3A and 3B applies to, for example, all of IDT electrodes 1, 2, 3, and 4 of the resonator groups 21 and 22 and the series-arm resonators 43, 44, and 45 and the parallel-arm resonators 46, 47, and 48 of the filter circuit 10. The exemplary illustrations in FIGS. 3A and 3B are referred to in order to describe the typical structure of the IDT electrode and the number of electrode fingers, the length of the electrode fingers, and so on of the actual IDT electrode, which are not limited to those in FIGS. 3A and 3B.

The IDT electrode 30 includes a pair of interdigital electrodes 30a and 30b opposed to each other. The interdigital electrode 30a includes multiple electrode fingers 31a that are in parallel or substantially in parallel with each other and a busbar electrode 32a with which the electrode fingers 31a are connected to each other. The interdigital electrode 30b includes multiple electrode fingers 31b that are in parallel or substantially in parallel with each other and a busbar electrode 32b with which the electrode fingers 31b are connected to each other. The electrode fingers 31a and 31b extend along a direction orthogonal or substantially orthogonal to the X-axis direction. The electrode fingers 31a and 31b and the busbar electrodes 32a and 32b are defined by electrodes 33 on a piezoelectric substrate 39, which are covered with a protective layer 34. The acoustic waves are propagated through the piezoelectric substrate 39 in the X-axis direction.

In the example in FIGS. 3A and 3B, a line width W of the electrode fingers 31a and 31b, a space width S between the electrode fingers 31a and 31b that are adjacent to each other, and an intersecting width L, which is the length by which the electrode fingers 31a and 31b are overlapped with each other viewed from the X-axis direction are exemplified as the electrode parameters. A pitch (W+S), which is a repetition period of the electrode fingers: the electrode fingers 31a and 31b, and a duty W/(W+S), which is the ratio of the line width with respect to the pitch, are also examples of the electrode parameters.

The inventor of preferred embodiments of the present invention calculated the attenuation characteristics for the filter 50 in which the electrode parameters of the IDT electrodes 1, 2, 3, and 4 in the additional circuit 20 are appropriately set as first and second examples to confirm the advantages described above. In addition, the inventor of preferred embodiments of the present invention calculated the attenuation characteristics for a filter in which the resonator group 22 in the additional circuit is omitted as a comparative example. In the filter of the comparative example, the cancel signal is generated only by the resonator group 21.

FIG. 4 is a circuit diagram illustrating an exemplary configuration of the filter according to the comparative example. As illustrated in FIG. 4, a filter 59 of the comparative example differs from the filter 50 in FIG. 1 in that the resonator group 22 is omitted in an additional circuit 29.

Table 1 indicates the values of the electrode parameters set for the IDT electrodes in the resonator groups in the additional circuits in the first and second examples and the comparative example.

TABLE 1

| | | | Electrode parameters | | |
|---|---|---|---|---|---|
| | | IDT | Intersecting | Pitch | Duty |
| | Resonator | elec- | width L | W + S | W/ |
| | group | trode | (μm) | (μm) | (W + S) |
| First | 21, 22 | 1, 3 | 15 | 4.392 | 0.50 |
| example | | 2, 4 | 15 | 4.719 | 0.50 |
| (FIG. 1) | | | | | |
| Second | 21 | 1 | 15 | 4.392 | 0.50 |
| example | | 2 | 15 | 4.719 | 0.50 |
| (FIG. 1) | 22 | 3 | 15 | 4.743 | 0.50 |
| | | 4 | 15 | 5.097 | 0.50 |
| Com- | 21 | 1 | 30 | 4.392 | 0.50 |
| parative | | 2 | 30 | 4.719 | 0.50 |
| example | | | | | |
| (FIG. 4) | | | | | |

As indicated in Table 1, in the first example, the electrode parameters of the IDT electrodes 1 and 2 in the resonator group 21 were made equal or substantially equal to the electrode parameters of the IDT electrodes 3 and 4 in the resonator group 22 in the filter 50 (FIG. 1).

In the second example, the electrode parameters of the IDT electrodes 1 and 2 in the resonator group 21 were made different from the electrode parameters of the IDT electrodes 3 and 4 in the resonator group 22 in the pitch in the filter 50 (FIG. 1).

In the comparative example, the intersecting width of the IDT electrodes 1 and 2 in the resonator group 21 was made twice the intersecting width of the IDT electrodes 1 and 2 in the resonator group 21 in the first and second examples in the filter 59 (FIG. 4).

The attenuation characteristics (the insertion losses between the terminals P1 and P2) of the filters in the first and second examples and the comparative example were calculated through simulation.

FIG. 5 is a graph showing the attenuation characteristics (the insertion losses between the terminals P1 and P2) of the filters in the first and second examples and the comparative example.

In FIG. 5, the transmission band B28ATx: about 703 MHz to about 733 MHz and the reception band B28ARx: about 758 MHz to about 788 MHz of Band B28A in Long Term Evolution (LTE) (registered trademark) are indicated as examples of the pass band and a stop band of each filter. In the transmission band B28ATx, an enlarged graph representing the practical insertion loss excluding matching loss is indicated.

Here, the notation of about 703 MHz to about 733 MHz represents a frequency range from about 703 MHz or more to about 733 MHz or less and the notation of about 758 MHz to about 788 MHz represents a frequency range from about 758 MHz or more to about 788 MHz or less.

As indicated in FIG. 5, in the reception band B28ARx, the insertion losses are increased (the attenuation characteristics are improved) in the first and second examples, compared with the insertion loss (the attenuation characteristics) in the comparative example. In addition, in a high pass portion of the transmission band B28ATx, the insertion loss of the first example is slightly increased (the bandpass characteristics are degraded), compared with the insertion loss (the bandpass characteristics) of the comparative example, while substantially the same insertion loss (substantially the same bandpass characteristics) as the insertion loss (the bandpass characteristics) of the comparative example is obtained in the second example.

The graph in FIG. 5 confirmed that the attenuation characteristics of the filter are capable of being improved by generating the cancel signals in a specific frequency band with the two resonator groups connected in parallel to each other (the first and second examples). In addition, the graph in FIG. 5 confirmed that the bandpass characteristics of the filter are capable of being improved by differentiating the parameters of the IDT electrodes between the two resonator groups (the second example).

### Second Preferred Embodiment

In a second preferred embodiment of the present invention, a multiplexer including the additional circuit 20 described in the first preferred embodiment will be described.

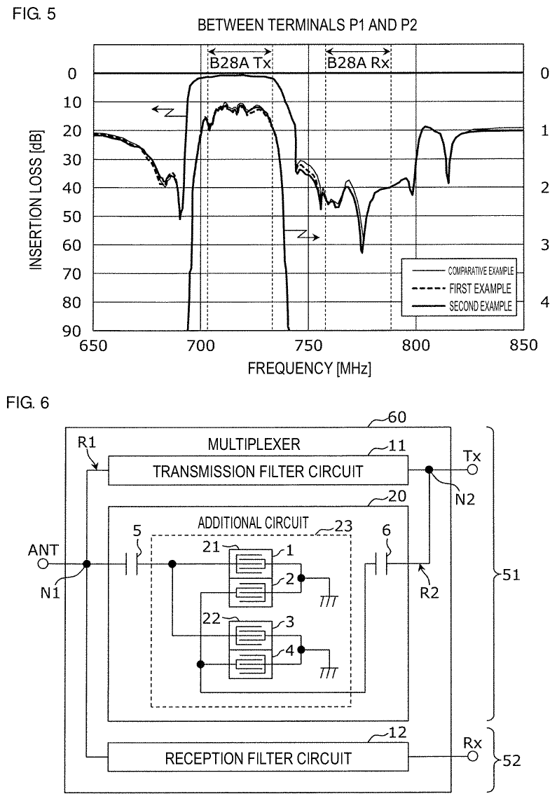

FIG. 6 is a circuit diagram illustrating an exemplary configuration of a multiplexer according to the second preferred embodiment. As illustrated in FIG. 6, a multiplexer 60 includes terminals ANT, Tx, and Rx, a transmission filter circuit 11, a reception filter circuit 12, and the additional circuit 20. In the multiplexer 60, the transmission filter circuit 11 and the additional circuit 20 define a transmission filter 51 and the reception filter circuit 12 defines a reception filter 52.

The transmission filter 51 is the same or substantially the same as the filter 50 in FIG. 1. Specifically, the transmission filter 51 results from replacement of the filter circuit 10 in the filter 50 with the transmission filter circuit 11. The multiplexer 60 is defined by connecting one end of the transmission filter 51 to one end of the reception filter 52.

With the multiplexer 60, it is possible to improve the attenuation characteristics of the transmission filter 51 and to improve isolation characteristics of the multiplexer 60 due to the feature of the additional circuit 20 in which the phases of the cancel signals are capable of being controlled with low loss and in a wide frequency band.

The inventor of preferred embodiments of the present invention calculated the isolation characteristics (the insertion loss between the terminals Rx and Tx) of the multiplexer 60 including the additional circuit having the same or substantially the same electrode parameters as those in the first and second examples and the comparative example in the first preferred embodiment set therein through simulation for confirmation of the advantages described above. The multiplexer 60 including the additional circuit corresponding to the first preferred embodiment is hereinafter referred to as first and second examples and a comparative example in the second preferred embodiment. In addition, the transmission band B28ATx and the reception band B28ARx described in the first preferred embodiment are examples of the pass band and the stop band, respectively, of the transmission filter circuit 11.

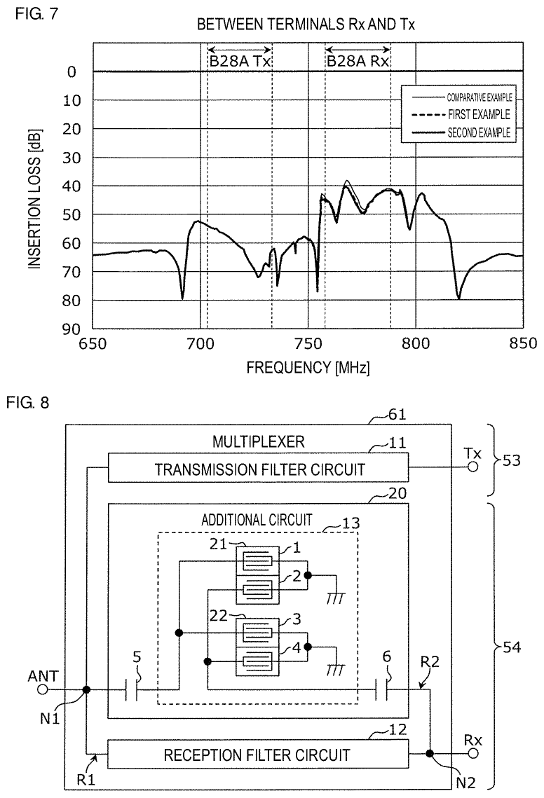

FIG. 7 is a graph indicating the isolation characteristics (the insertion losses between the terminals Rx and Tx) of the multiplexers in the first and second examples and the comparative example.

As indicated in FIG. 7, in the reception band B28ARx, the insertion losses are increased (the isolation characteristics are improved) in the first and second examples, compared with the insertion loss (the isolation characteristics) in the comparative example.

The graph in FIG. 7 confirmed that the isolation characteristics of the multiplexer are capable of being improved by using the additional circuit generating the cancel signals in a specific frequency band with the two resonator groups connected in parallel to each other (the first and second examples).

Although the additional circuit 20 is connected in parallel to the transmission filter circuit 11 in the multiplexer 60, the position at which the additional circuit is connected in the multiplexer is not limited to this example.

As another example, the additional circuit 20 may be connected in parallel to the reception filter circuit 12.

FIG. 8 is a circuit diagram illustrating another exemplary configuration of a multiplexer according to the second preferred embodiment. A multiplexer 61 in FIG. 8 differs from the multiplexer 60 in FIG. 6 in that the additional circuit 20 is connected in parallel to the reception filter circuit 12, instead of in parallel to the transmission filter circuit 11. In the multiplexer 61, the transmission filter circuit 11 includes a transmission filter 53 and the reception filter circuit 12 and the additional circuit 20 define a reception filter 54.

The reception filter 54 is the same or substantially the same as the filter 50 in FIG. 1. Specifically, the reception filter 54 results from replacement of the filter circuit 10 in the filter 50 with the reception filter circuit 12. The multiplexer 61 is defined by connecting one end of the transmission filter 53 to one end of the reception filter 54.

With the multiplexer 61, it is possible to improve the attenuation characteristics of the reception filter 54 and to improve the isolation characteristics of the multiplexer 61 due to the feature of the additional circuit 20 in which the phases of the cancel signals are capable of being controlled with low loss and in a wide frequency band.

As another example, the additional circuit 20 may be connected across the transmission filter circuit 11 and the reception filter circuit 12.

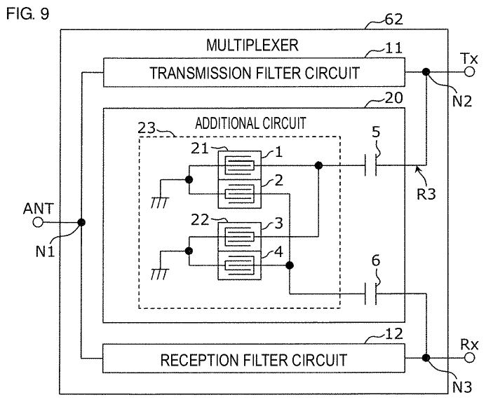

FIG. 9 is a circuit diagram illustrating another exemplary configuration of a multiplexer according to the second preferred embodiment. A multiplexer 62 in FIG. 9 differs from the multiplexers 60 and 61 in FIG. 6 and FIG. 8, respectively, in that the additional circuit 20 is connected across the transmission filter circuit 11 and the reception filter circuit 12.

Specifically, in the multiplexer 62 in which one end of the transmission filter circuit 11 is connected to one end of the reception filter circuit 12, the additional circuit 20 is provided on a signal path R3 with which the other end of the transmission filter circuit 11 is connected to the other end of the reception filter circuit 12. Specifically, the additional circuit 20 is connected to the node N2 between the transmission filter circuit 11 and the terminal Tx and a node N3 between the reception filter circuit 12 and the terminal Rx.

In the multiplexer 62, the additional circuit 20 controls the phase of the cancel signal against a signal component that is not desired and that is transmitted between the terminals Rx and Tx with low loss and in a wide frequency band. Accordingly, the attenuation characteristics between the terminals Rx and Tx are effectively improved so as to improve the isolation characteristics of the multiplexer 62.

Although the filters and the multiplexers according to preferred embodiments of the present invention are described above, the present invention is not limited to the individual preferred embodiments. Various modifications that are conceived by persons of ordinary skill in the art and that are made to the preferred embodiments resulting from a combination of components in different preferred embodiments may be included in the range of one or multiple aspects of the present invention without departing from the spirit and scope of the present invention.

A filter according to a preferred embodiment of the present invention includes a filter circuit and an additional circuit that are connected in parallel to each other. The filter circuit has a pass band. The additional circuit includes a first resonator group and a second resonator group each of which includes multiple interdigital transducer electrodes arranged in line in an acoustic-wave propagation direction and which are connected in parallel to each other. The additional circuit generates a signal having a phase opposite to that of a signal component in a specific frequency band that is not included in the pass band, among signals transmitted through the filter circuit.

With the above configuration, the filter generates a cancel signal, which is a signal having a phase opposite to that of a signal component in a specific frequency band, with the two resonator groups connected in parallel to each other. Accordingly, since the cancel signal is capable of being generated with lower loss and in a wider frequency band, compared with the case in which the cancel signal is generated with one resonator group, it is possible to obtain a filter having the excellent attenuation characteristics.

A filter according to a preferred embodiment of the present invention includes a first terminal and a second terminal thorough which a radio-frequency signal is input and output, a filter circuit that defines a signal path with which the first terminal is connected to the second terminal, and an additional circuit that is connected to a first node between the first terminal and the filter circuit on the signal path and a second node between the second terminal and the filter circuit on the signal path and that defines another signal path with which the first node is connected to the second node. The filter circuit has a pass band. The additional circuit includes, on the other signal path, a parallel circuit in which a first resonator group and a second resonator group, each of which includes multiple interdigital transducer electrodes arranged in line in an acoustic-wave propagation direction, are connected in parallel to each other and a capacitor element connected in series to the parallel circuit. The additional circuit generates a signal having a phase opposite to that of a signal component in a frequency band that is not included in the pass band, which is transmitted through the filter circuit.

With the above configuration, the frequency band in which the amplitude of the cancel signal is capable of being controlled is fixed in accordance with the capacitance value of the capacitor element. In other words, the additional circuit generates the cancel signal against a signal component in a specific frequency band. The specific frequency band may be, for example, a frequency band determined based on the capacitance values of the capacitor elements 5 and 6.

The two resonator groups in the additional circuit do not control the phases of the two cancel signals in two separate frequency bands separately but control the phases of the cancel signals in continuous frequency bands which are in a specific frequency band and at least a portion of which is overlapped. In other words, the additional circuit controls the phases of the cancel signals in a specific frequency band with the two resonator groups connected in parallel to each other.

Accordingly, since the cancel signals are capable of being generated with lower loss and in a wider frequency band, compared with the case in which the cancel signal is generated with one resonator group, it is possible to obtain a filter having the excellent attenuation characteristics.

Parameters of the interdigital transducer electrodes of the first resonator group may be different from parameters of the interdigital transducer electrodes of the second resonator group.

With the above configuration, the frequencies of unnecessary responses caused by the two respective resonator groups are shifted from each other. This reduces the influence of the unnecessary responses on the bandpass characteristics of the filter, compared with a case in which the parameters of the two resonator groups are equal or substantially equal to each other, that is, a case in which the frequencies of the unnecessary responses caused by the two resonator groups coincide with each other. As a result, it is possible to reduce the insertion loss in the pass band, in addition to the improvement of the attenuation characteristics.

The filter circuit may be, for example, an acoustic wave filter circuit including multiple acoustic wave resonators.

With the above configuration, since both of the filter circuit and the additional circuit include the acoustic wave resonators, it is possible to provide the entire filter on one piezoelectric substrate.

A multiplexer according to a preferred embodiment of the present invention includes a first filter and a second filter. One end of the first filter is connected to one end of the second filter. At least one of the first filter and the second filter is any of the filters described above.

A multiplexer according to a preferred embodiment of the present invention includes a first filter and a second filter, one end of the first filter being connected to one end of the second filter, and an additional circuit provided on a signal path with which the other end of the first filter is connected to the other end of the second filter. The additional circuit includes, on the signal path, a parallel circuit in which a first resonator group and a second resonator group are connected in parallel to each other and a capacitor element connected in series to the parallel circuit.

With the above configuration, it is possible to obtain a multiplexer having the excellent isolation characteristics due to the feature of the additional circuit in which the phases of the cancel signals are capable of being controlled with low loss and in a wide frequency band.

Preferred embodiments of the present invention are each capable of being widely used in a communication device, such as, for example, a mobile phone, as a filter and a multiplexer, which include an additional circuit.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter comprising:
a filter circuit; and
an additional circuit connected in parallel to the filter circuit; wherein
the filter circuit has a pass band; and
the additional circuit includes a first resonator group and a second resonator group each of which includes a plurality of interdigital transducer electrodes arranged in line in an acoustic-wave propagation direction and which are connected in parallel to each other.

2. A filter comprising:
a first terminal and a second terminal through which a radio-frequency signal is input and output;
a filter circuit defining a signal path with which the first terminal is connected to the second terminal; and
an additional circuit connected to a first node between the first terminal and the filter circuit on the signal path and a second node between the second terminal and the filter circuit on the signal path and defining another signal path with which the first node is connected to the second node; wherein
the filter circuit has a pass band; and
the additional circuit includes, on the other signal path, a parallel circuit in which a first resonator group and a second resonator group, each of which includes a plurality of interdigital transducer electrodes arranged in line in an acoustic-wave propagation direction, are connected in parallel to each other and a capacitor element connected in series to the parallel circuit.

3. The filter according to claim 1, wherein the additional circuit generates a signal having a phase opposite to a phase of a signal component in a specific frequency band that is not included in the pass band, among signals transmitted through the filter circuit.

4. The filter according to claim 1, wherein parameters of the plurality of interdigital transducer electrodes of the first resonator group are different from parameters of the plurality of interdigital transducer electrodes of the second resonator group.

5. The filter according to claim 1, wherein the filter circuit is an acoustic wave filter circuit including a plurality of acoustic wave resonators.

6. A multiplexer comprising:
a first filter; and
a second filter; wherein
one end of the first filter is connected to one end of the second filter; and
at least one of the first filter and the second filter is the filter according to claim 1.

7. A multiplexer comprising:
a first filter:
a second filter; and
an additional circuit; wherein
one end of the first filter is connected to one end of the second filter;
the additional circuit is provided on a signal path with which another end of the first filter is connected to another end of the second filter; and
the additional circuit includes, on the signal path, a parallel circuit in which a first resonator group and a second resonator group are connected in parallel to each other and a capacitor element connected in series to the parallel circuit.

8. The filter according to claim 2, wherein the additional circuit generates a signal having a phase opposite to a phase of a signal component in a specific frequency band that is not included in the pass band, among signals transmitted through the filter circuit.

9. The filter according to claim 2, wherein parameters of the plurality of interdigital transducer electrodes of the first resonator group are different from parameters of the plurality of interdigital transducer electrodes of the second resonator group.

10. The filter according to claim 2, wherein the filter circuit is an acoustic wave filter circuit including a plurality of acoustic wave resonators.

11. The multiplexer according to claim 6, wherein the additional circuit generates a signal having a phase opposite to a phase of a signal component in a specific frequency band that is not included in the pass band, among signals transmitted through the filter circuit.

12. The multiplexer according to claim 6, wherein parameters of the plurality of interdigital transducer electrodes of the first resonator group are different from parameters of the plurality of interdigital transducer electrodes of the second resonator group.

13. The multiplexer according to claim 6, wherein the filter circuit is an acoustic wave filter circuit including a plurality of acoustic wave resonators.

14. A multiplexer comprising:
a first filter; and
a second filter; wherein
one end of the first filter is connected to one end of the second filter; and
at least one of the first filter and the second filter is the filter according to claim 2.

15. The multiplexer according to claim 14, wherein the additional circuit generates a signal having a phase opposite to a phase of a signal component in a specific frequency band that is not included in the pass band, among signals transmitted through the filter circuit.

16. The multiplexer according to claim 14, wherein parameters of the plurality of interdigital transducer electrodes of the first resonator group are different from parameters of the plurality of interdigital transducer electrodes of the second resonator group.

17. The multiplexer according to claim 14, wherein the filter circuit is an acoustic wave filter circuit including a plurality of acoustic wave resonators.

18. The multiplexer according to claim 7, wherein each of the first resonator group and the second resonator group includes a plurality of interdigital transducer electrodes.

19. The multiplexer according to claim 18, wherein parameters of the plurality of interdigital transducer electrodes of the first resonator group are different from parameters of the plurality of interdigital transducer electrodes of the second resonator group.
